(19) United States
(12) Patent Application Publication
(10) Pub. No.: US 2016/0262290 A1
(43) Pub. Date: Sep. 8, 2016

(54) HEAT SINK-BASED SINGLE-BOARD COMPUTER HOLDER ASSEMBLY

(71) Applicant: ADLINK TECHNOLOGY INC., New Taipei City (TW)

(72) Inventor: Zheng-Ming CHEN, New Taipei City (TW)

(21) Appl. No.: 14/952,557

(22) Filed: Nov. 25, 2015

(30) Foreign Application Priority Data
Mar. 2, 2015 (TW) 104203067

(51) Int. Cl. H05K 7/20; F28F 3/04

(52) U.S. Cl. CPC H05K 7/20418; F28F 3/04

(57) ABSTRACT

A heat sink-based single-board computer holder assembly includes heat sink including base, mounting flanges located at opposing top and bottom sides of base, insertion slot unit located at mounting flange, first slot and second slots located at front side of mounting flange, a plurality of third slots located at back side of mounting flange between first slot and second slots, and bevel guide facets located at two distal ends of first slot, and positioning mechanism including two fastening members inserted through bevel guide facets and first slot and second slots at two mounting flanges, and two pair of wedge-shaped sliding blocks mounted on fastening members and abutted against bevel guide facets and movable along bevel guide facets upon rotating fastening members. The structural design of insertion slot units can easily be made by using computer numerically controlled machine tool to perform linear milling process, simplifying manufacturing process and reducing cost.

This application claims the priority benefit of Taiwan patent application number 104203067, filed on Mar. 2, 2015.

### BACKGROUND OF THE INVENTION

1. Field of the Invention

The present invention relates to a heat sink-based single-board computer holder assembly, which comprises a heat sink having an insertion slot unit located at each of two mounting flanges at opposing top and bottom sides of a base thereof, and a positioning mechanism comprising two fastening members respectively inserted through pairs of wedge-shaped sliding blocks and the insertion slot units of heat sink. Each fastening member is rotatable to move the wedge-shaped sliding blocks in or out of the mounting flanges of the heat sink, wherein the structural design of the insertion slot units can easily be made by using a computer numerically controlled machine tool to perform a linear milling process, simplifying the manufacturing process and effectively reducing the manufacturing cost.

2. Description of the Related Art

Following fast development of technology, advanced computers, notebooks and many other electronic products have been continuously created and widely used in every corner of the society. It is the market trend to create electronic products having the characteristics of strong computing capabilities, high operating speed and small size.

With the development of computer open architecture and standardization of computer hardware and software, and the progress of continuous functional expansion and upgrade, industrial computers are created for application in different fields, such as industrial control, industrial automation, network and communication equipments, machine vision, intelligent transport system, etc. for military, transportation, aerospace and other industrial applications to shoulder important tasks, satisfying the requirements of clients for the implementation of high-performance operations under customer-specific specifications and harsh environments.

An industrial computer generally comprises a plurality of single-board computers (SBCs), embedded boards, backplane modules, and other relevant components. A single-board computer has mounted therein processors, chipsets, input/output ports, built-in power supply input, memory module, hard disk drive and system interfaces, providing a plug and play hardware platform and expansion slots for added functions. Single-board computers are commonly smaller than the motherboard of a personal computer, enhancing the flexibility of use in any of fixed or mobile embedded systems and other industrial computers. However, due to small size and high operating speed, a single-board computer generates a large amount of heat during its operation. How to maintain a single-board computer under the designed working temperature range for normal functioning has been regarded by the industry as an important problem to be solved.

It is the normal way to use each single-board computer with a respective heat sink-based single-board computer holder assembly, keeping the heat sink A of the heat sink-based single-board computer holder assembly in abutment against the heat-generating components (such as CPU, image processor, chipset, etc.) at the motherboard of the single-board computer. After fixation of a single-board computer to the heat sink A of a heat sink-based single-board computer holder assembly and insertion of the single-board computer with the heat sink-based single-board computer holder assembly into one guide groove B1 in an accommodation chamber B0 inside a machine housing B, one side of the heat sink A opposite to the wedge-shaped sliding blocks A22 is tightly secured to the respective guide groove B1 for heat transfer. When multiple single-board computers with the respective heat sink-based single-board computer holder assemblies are inserted into the respective guide grooves B1 in the accommodation chamber B0 inside the machine housing B, the single-board computers are kept in parallel. During operation of the single-board computers, waste heat generated by the heat-generating components of the single-board computers is rapidly transferred by the respective heat sinks A to the metal machine housing B for quick dissipation.

However, the through hole A11 that cuts through the mounting flange A1 of the heat sink A has an oblong cross section. The screw rod A21 of each fastening member A2 is inserted through the respective two wedge-shaped sliding blocks A22 and the through hole A11 in the respective mounting flange A1 of the heat sink A, keeping the wedge-shaped sliding blocks A22 in abutment against respective beveled guide facets A12. When rotating the screw rod A21, the wedge-shaped sliding blocks A22 are moved along the respective beveled guide facets A12. According to this prior art design, the structural design of the depth and configuration of the through hole A11 cannot be easily made by using a computer numerically controlled (CNC) machine tool through a drilling, milling or broaching machining process. The design of the through hole A11 should be implemented by the process of discharge machining, ultrasonic machining and/or laser machining, complicating the fabrication, increasing the manufacturing cost, and restricting the manufacturing flexibility.

### SUMMARY OF THE INVENTION

The present invention has been accomplished under the circumstances in view. It is therefore one object of the present invention to provide a heat sink-based single-board computer holder assembly, which comprises a heat sink and a positioning mechanism. The heat sink comprises a base, two mounting flanges respectively extended from opposing top and bottom sides of the base, an insertion slot unit transversely located at each mounting flange, and two bevel guide facets located at each mounting flange and sloping forwardly inwards and respectively disposed at two opposite ends of the associating insertion slot unit. Each insertion slot unit comprises a first slot located at a front side of the respective mounting flanges between the respective two bevel guide facets, a second slot located at each bevel guide facet, a plurality of third slots located at an opposing back side of the respective mounting flanges and respectively disposed between the first slot and the two second slots, and two stop blocks respectively disposed between two opposite ends of the first slot and the two second slots. The positioning mechanism comprises two fastening members respectively inserted through the insertion slot units at the two mounting flanges of the heat sink, and two pair of wedge-shaped sliding blocks respectively bilaterally mounted on the mounting flanges of the heat sink. Each wedge-shaped sliding block comprises a through hole cut through opposing front and back sides thereof, a beveled stop facet located at the front side thereof and abutted against one respective bevel guide facet of the heat sink, and a planar abutment surface extended from a border side of the beveled stop facet. Each fastening member is rotatable to move the respective two wedge-shaped sliding blocks along the respective bevel guide facets between a first position where the abutment surface of each wedge-shaped sliding block is protruded over the front side of the respective mounting flanges and a second position where the abutment surface of each wedge-shaped sliding block is retracted below the front side of the respective mounting flanges. The structural design of the insertion slot units can easily be made by using a computer numerically controlled machine tool to perform a linear milling process simplifying the manufacturing process to effectively reduce the manufacturing cost.

Further, in application of the present invention, insert the respective mounting flanges of the heat sink into one respective sliding guide portion in the machine housing, and then attach a hand tool to the head of the screw rod of each fastening member and then operate the hand tool to fasten tight each fastening member. When fastening up one fastening member, the outer thread of the screw rod is threaded into an inner thread in the through hole of one respective wedge-shaped sliding block to further move the respective two wedge-shaped sliding blocks along the respective bevel guide facets at the respective mounting flanges in direction toward each other. Because the inner dimension of the insertion slot unit is larger than the outer diameter of the screw rod, the screw rod can be moved with the respective two wedge-shaped sliding blocks in the relative to the respective mounting flanges. Further, the stop blocks of each insertion slot unit at the respective mounting flanges prohibit the screw rod from falling out of the respective mounting flanges. When fastening tight each fastening member, the abutment surface of each wedge-shaped sliding block and the back side of the mounting flange are forced to abut against sidewalls of the respective guide portion of the machine housing to lock the respective heat sink-based single-board computer holder assembly to the machine housing for transferring heat. Further, except for the third slots of the respective mounting flanges, the back side of each mounting flange has no other groove therein. A large contact surface area is provided at each mounting flange for positive contact with the respective guide portion of the machine housing, enhancing heat dissipating performance.

In an alternate form of the present invention, the insertion slot unit at each mounting flange of the heat sink simply comprises one slot located at the back side of the mounting flange and cut through the two bevel guide facets. The slot of the insertion slot unit is made by linear milling. This second embodiment simplifies the manufacturing process of the heat sink-based single-board computer holder assembly to reduce the cost.

Further, the inner thread can be eliminated from the through hole of the respective wedge-shaped sliding block. In this case, the screw rod of each fastening member is inserted through the through hole of the respective two wedge-shaped sliding blocks with the outer thread thereof threaded into the inner thread of one respective screw nut. In installation, the user can use a hand tool to rotate the screw nut. When rotating the screw nut at this time, the screw rod of the fastening member is moved to carry the respective two wedge-shaped sliding blocks toward each other, forcing the two wedge-shaped sliding blocks and the respective mounting flange to abut against the respective guide portion of the machine housing for transferring heat.

Other advantages and features of the present invention will be fully understood by reference to the following specification in conjunction with the accompanying drawings, in which like reference signs denote like components of structure.

### BRIEF DESCRIPTION OF THE DRAWINGS

FIG. 1 is an oblique top elevational view of a heat sink-based single-board computer holder assembly in accordance with the present invention.

FIG. 2 is an exploded view of the heat sink-based single-board computer holder assembly in accordance with the present invention.

FIG. 3 corresponds to FIG. 2 when viewed from another angle.

FIG. 4 is a sectional top view of the present invention before fixation.

FIG. 5 is a sectional top view of the present invention after fixation.

FIG. 6 is an oblique top elevational view of the present invention after fixation.

FIG. 7 is a sectional top view of an alternate form of the heat sink-based single-board computer holder assembly in accordance with the present invention.

FIG. 8 is an exploded view of the alternate form of the heat sink-based single-board computer holder assembly in accordance with the present invention.

FIG. 9 is an exploded view of a heat sink-based single-board computer holder assembly and a machine housing according to the prior art.

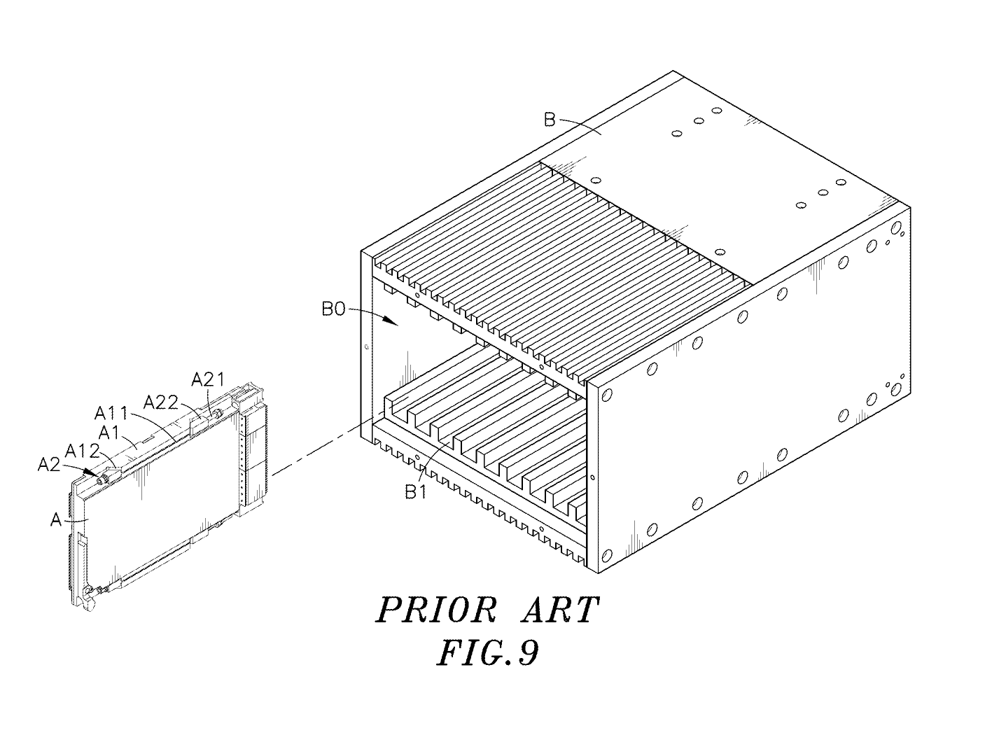

FIG. 10 is an exploded view of a heat sink-based single-board computer holder assembly according to the prior art.

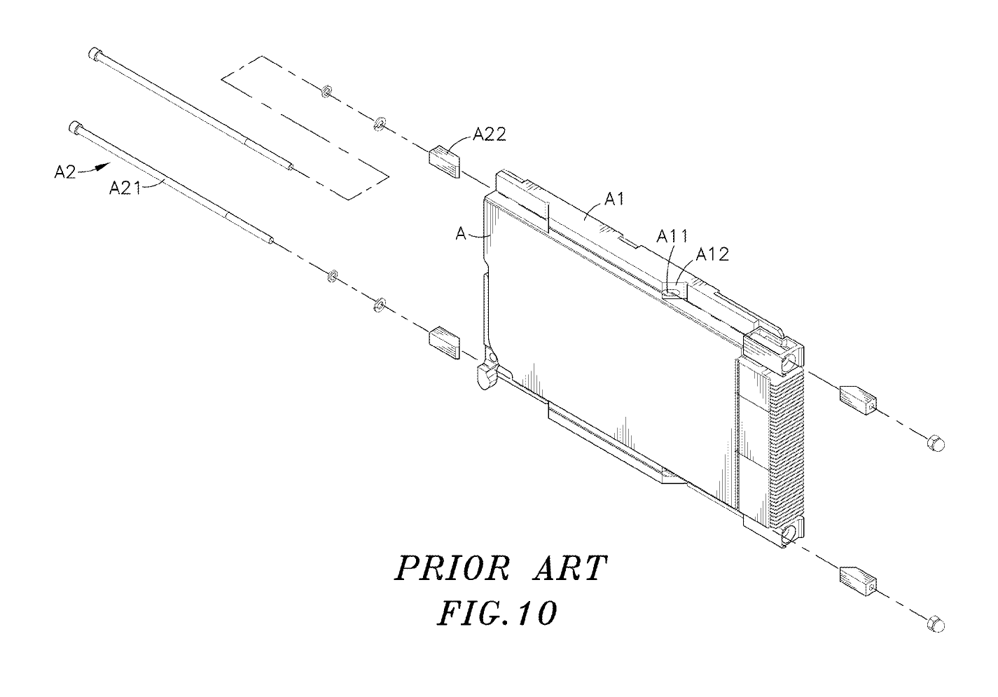

### DETAILED DESCRIPTION OF THE PREFERRED EMBODIMENT

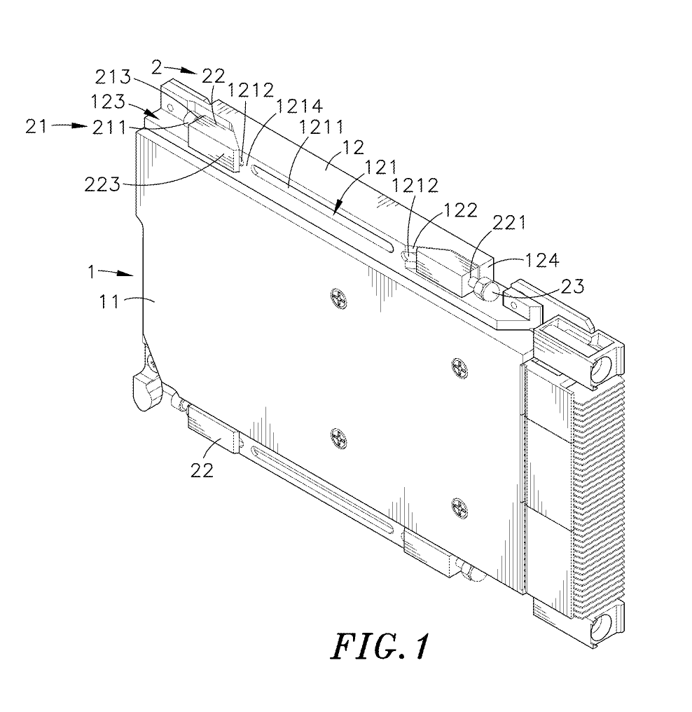

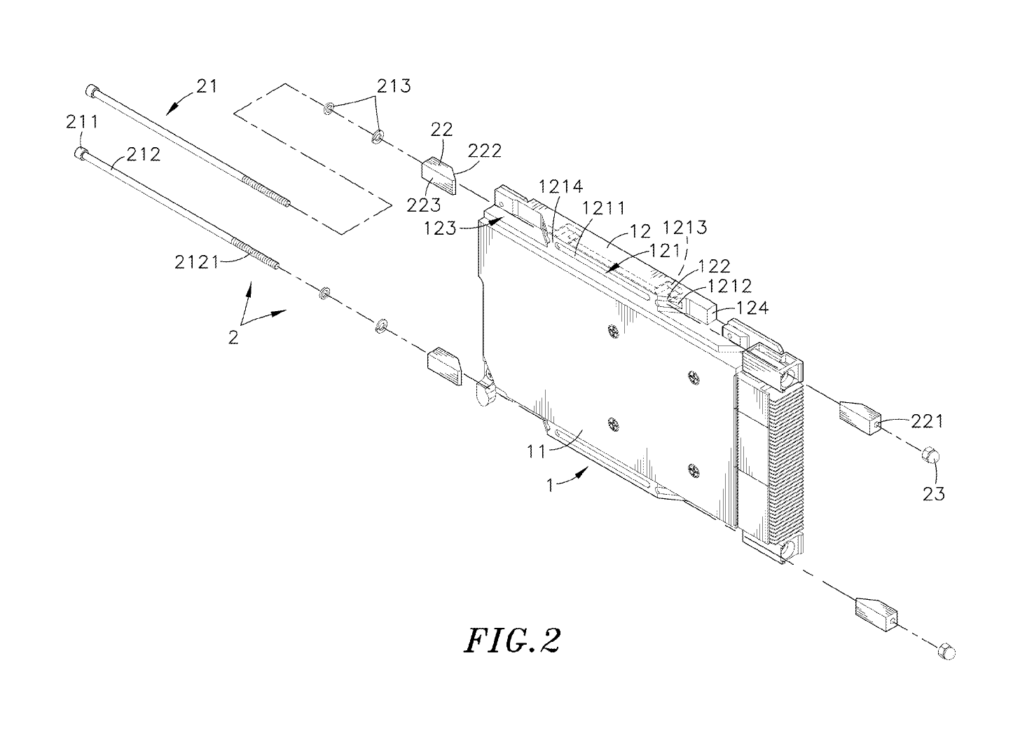

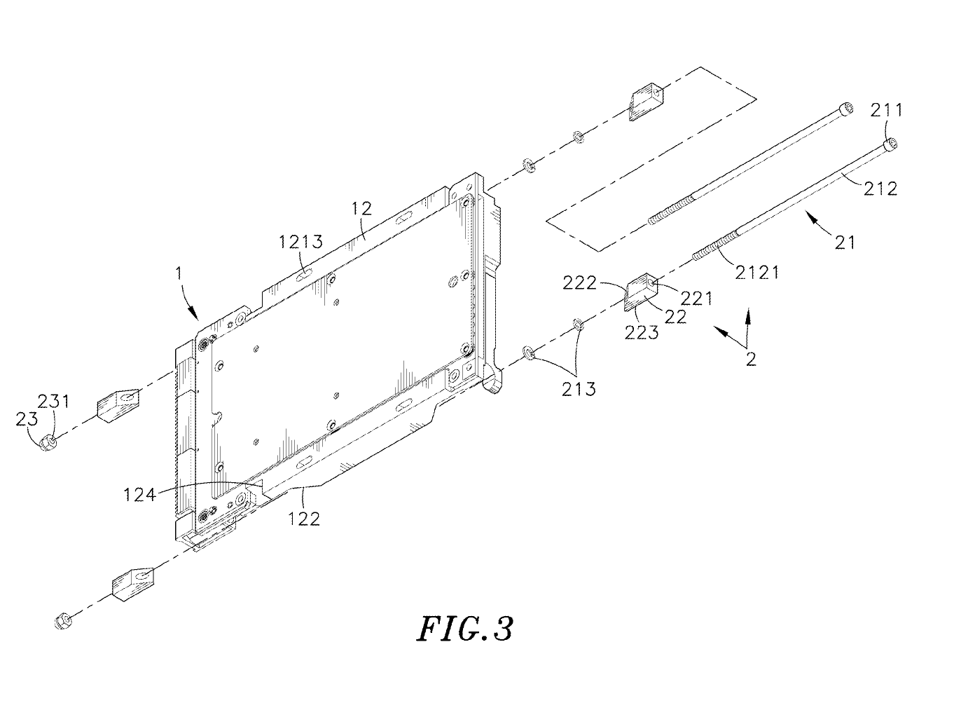

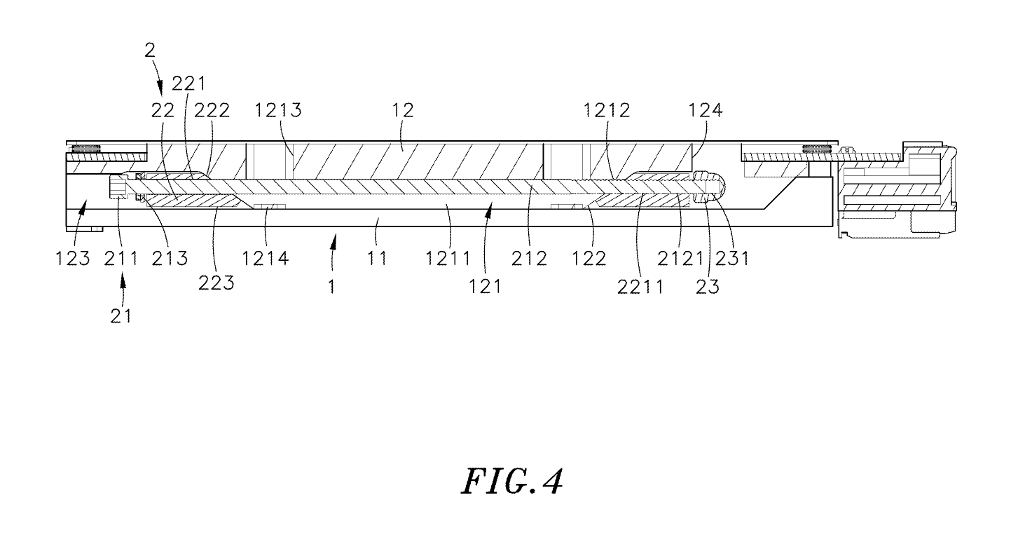

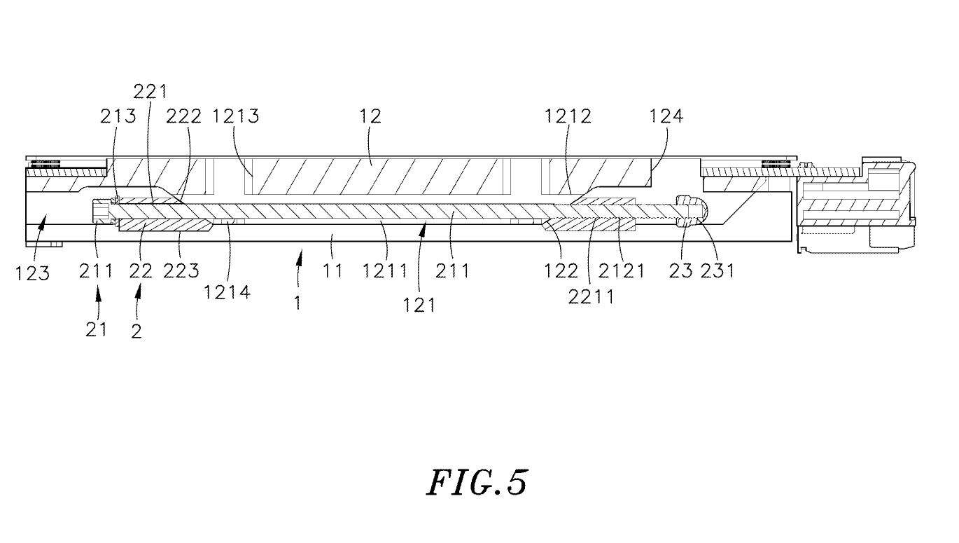

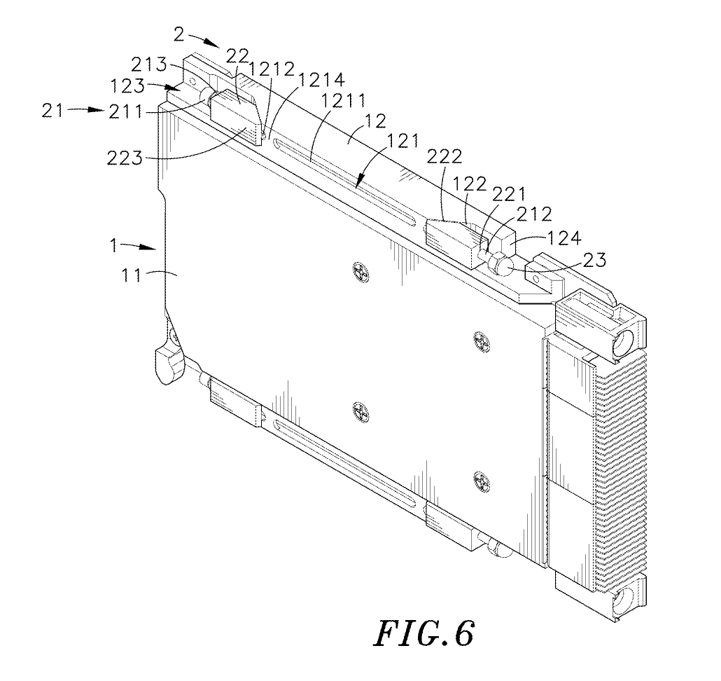

Referring to FIGS. 1-6, an oblique top elevational view of a heat sink-based single-board computer holder assembly in accordance with the present invention, an exploded view of the invention, another exploded view of the invention, a sectional top view of the invention before fixation, a sectional top view of the invention after fixation and an oblique top elevational applied view of the invention are shown. The heat sink-based single-board computer holder assembly comprises a heat sink 1, and a positioning mechanism 2.

The heat sink 1 comprises a plate-shaped base 11 having two opposite long sides respectively located at opposing top and bottom sides thereof, a mounting flange 12 located at each of the opposing top and bottom sides (the two long sides) of the base 11 and extending along the length thereof, an insertion slot unit 121 transversely located at each mounting flange 12, and two bevel guide facets 122 located at each mounting flange 12 and sloping forwardly inwards and respectively disposed at two opposite ends of the associating insertion slot unit 121. The insertion slot unit 121 at each mounting flange 12 comprises a first slot 1211 located at a front side of the mounting flange 12 between the two bevel guide facets 122 and formed by milling, two second slots 1212 located at respective bevel guide facets 122 and formed by milling, a plurality of third slots 1213 located at an opposing back side of the respective mounting flange 12 and respectively disposed between the two opposite ends of the first slot 1211 and the two second slots 1212 and formed by milling, and two stop blocks 1214 respectively disposed between the two opposite ends of the first slot 1211 and the two second slots 1212.

The heat sink 1 further comprises two stepped guideways 123 located at each mounting flange 12 and respectively outwardly extended from the respective two bevel guide facets 122 in reversed directions, and a notch 124 located at each mounting flange 12 and transversely extended from one stepped guideway 123 to the back side of the respective mounting flange 12. Further, the heat sink 1 is preferably made from a thermally conductive material selected from the group of aluminum, copper, and their alloys. Screws can installed to affix to a circuit board (such as motherboard, interface card) of a single-board computer or embedded system to the surface of the base 11, keeping the CPU, image processor (such as GMCH), chips (such as ICH, RAM) and other heat-generating components of the circuit board (not shown) in abutment against the surface of the base 11. In actual application, the heat sink 1 can be configured to provide fins and/or heat pipes to enhance heat dissipation performance.

The positioning mechanism 2 comprises two fastening member 21 and two pair of wedge-shaped sliding blocks 22. Each fastening member 21 comprises a screw rod 212, a head 211 located at one end of the screw rod 212, and an outer thread 2121 extending around the periphery of an opposite end of the screw rod 212. Further, one or multiple cushion rings 213 are mounted on the screw rod 212 of each fastening member 21. Each wedge-shaped sliding block 22 comprises a through hole 221 cut through opposing front and back sides thereof, and a beveled stop facet 222 located at the front side thereof, a planar abutment surface 223 located at the periphery thereof and extended from a border side of the beveled stop facet 222. Further, one of each pair of wedge-shaped sliding blocks 22 is configured to provide an inner thread 2211 in the through hole 221 thereof. The screw rod 212 of each fastening member 21 is inserted through the through hole 221 of one of each pair wedge-shaped sliding blocks 22, and then threaded with the outer thread 2121 thereof into the inner thread 2211 in the through hole 221 of the other of the same pair of wedge-shaped sliding blocks 22. Further, a screw nut 23 can be threaded with the inner thread 231 thereof onto the outer thread 2121 of the screw rod 212 of each fastening member 21.

When assembling the heat sink-based single-board computer holder assembly, insert the screw rod 212 of each fastening member 21 of the positioning mechanism 2 through respective cushion rings 213 and the through hole 221 of one of the respective pair of wedge-shaped sliding blocks 22 and the insertion slot unit 121 at one respective mounting flange 12 of the heat sink 1, and then thread the outer thread 2121 of the screw rod 212 into the inner thread 2211 in the through hole 221 of the other of the respective pair of wedge-shaped sliding blocks 22, and then, if necessary, thread the inner thread 231 of one screw nut 23 onto the outer thread 2121 of the screw rod 212 to abut the screw nut 23 against the other of the respective pair of wedge-shaped sliding blocks 22. At this time, the two wedge-shaped sliding blocks 22 are respectively positioned on the respective stepped guideways 123 at the respective mounting flange 12 with the beveled stop facet 222 of the respective wedge-shaped sliding blocks 22 respectively abutted against the bevel guide facets 122 of the respective mounting flange 12, and the abutment surfaces 223 of the respective wedge-shaped sliding blocks 22 are respectively kept in flush with the respective mounting flange 12.

When mounting the heat sinks 1 of multiple heat sink-based single-board computer holder assemblies in a machine housing (not shown), insert the respective mounting flanges 12 at the opposing top and bottom sides of the respective bases 11 of the heat sinks 1 of the multiple heat sink-based single-board computer holder assemblies into respective sliding guide portions (such as sliding grooves or position-limit channels) in the machine housing in parallel, and then attach a hand tool (such as hex wrench or screwdriver) to the head 211 of each fastening member 21 and operate the hand tool to fasten tight each fastening member 21. When fastening up one fastening member 21, the outer thread 2121 of the screw rod 212 is threaded into the inner thread 2211 in the through hole 221 of the respective wedge-shaped sliding block 22 to further move the beveled stop facets 222 of the respective two wedge-shaped sliding blocks 22 along the respective bevel guide facets 122 at the respective mounting flange 12 in direction toward each other. Because the inner dimension of the insertion slot unit 121 is larger than the outer diameter of the screw rod 212, the screw rod 212 can be moved with the respective two wedge-shaped sliding blocks 22 relative to the respective mounting flange 12. Further, the stop block 1214 of each insertion slot unit 121 at the respective mounting flange 12 prohibits the screw rod 212 from falling out of the respective mounting flange 12.

When fastening up each fastening member 21 to move the beveled stop facets 222 of the respective wedge-shaped sliding blocks 22 along the respective bevel guide facets 122 at the respective mounting flange 12, the abutment surfaces 223 of the respective wedge-shaped sliding blocks 22 are moved to protrude over the front side of the respective mounting flange 12 into abutment against one sidewall of each respective guide portion of the machine housing, locking the respective heat sink-based single-board computer holder assembly to the machine housing. Further, except for the third slots 1213 on the respective mounting flanges 12, the back side of each mounting flange 12 has no groove therein, which makes it a large contact surface area at each mounting flange 12 for positive contact with the respective guide portion of the machine housing, enhancing heat dissipating performance. Further, each insertion slot unit 121 of the heat sink 1 can easily be made by using a computer numerically controlled machine tool to perform a linear milling process without applying other different manufacturing processes (such as discharge machining, ultrasonic machining, laser machining, etc.). Thus, the invention simplifies the manufacturing process for mass production to reduce the manufacturing cost, increases the dimensional accuracy, and enhances the product quality.

During operation of the heat-generating components of the circuit board of the single-board computer, waste heat generated by the heat-generating components of the circuit board is absorbed by the heat sink 1 that is selected from the material group of aluminum, copper and their alloys, and then transferred by the mounting flanges 12 of the heat sink 1 to the internal metal guide portions of the metal machine housing for quick dissipation into the outside open air, maintaining normal functioning of the single-board computers.

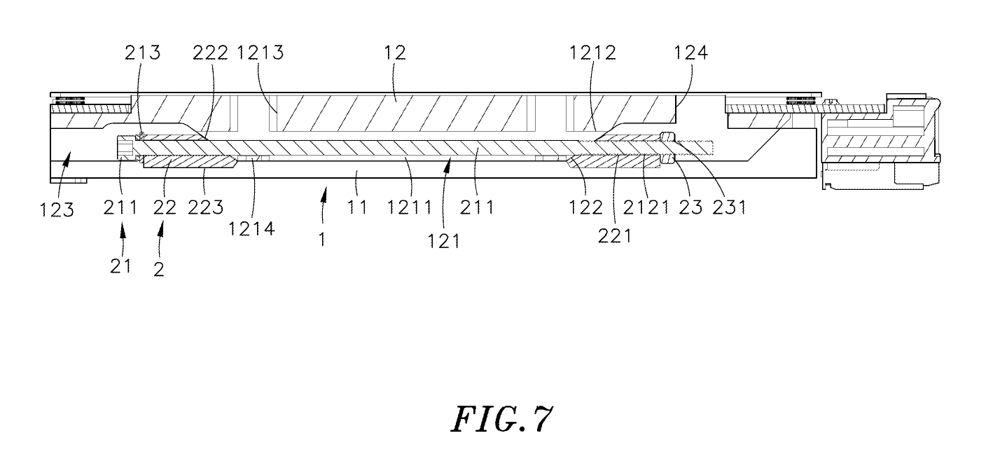

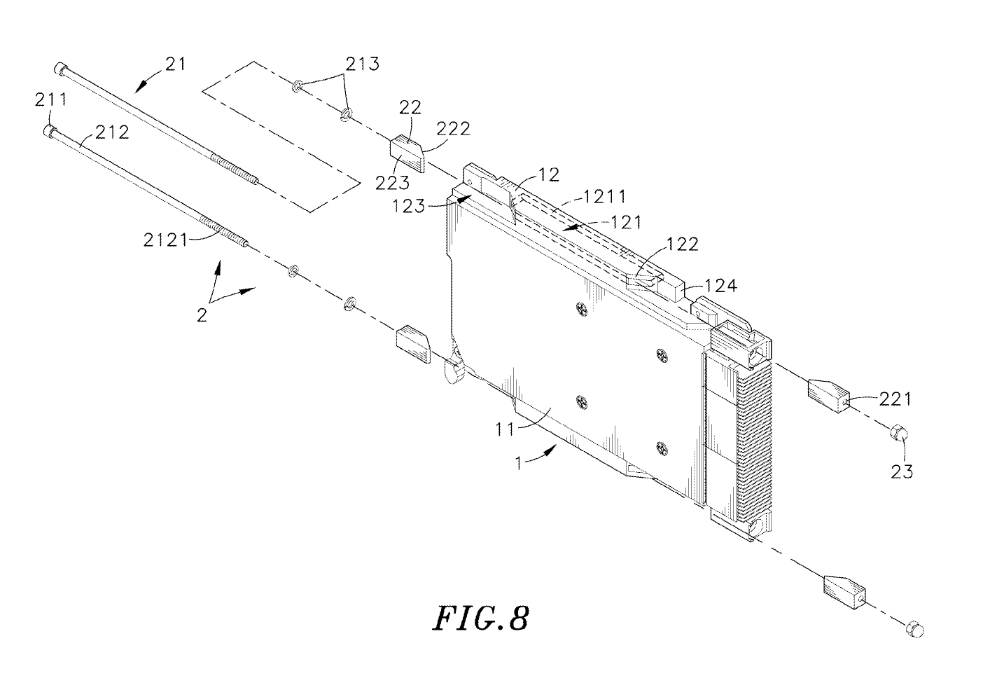

Referring to FIGS. 7 and 8, two alternate forms of the heat sink-based single-board computer holder assembly are shown. In the aforesaid first embodiment of the present invention as shown in FIGS. 1-6, the insertion slot unit 121 at each mounting flange 12 of the heat sink 1 comprises a first slot 1211 located at the front side of the respective mounting flange 12, two second slots 1212 respectively located at the two bevel guide facets 122 at the respective mounting flange 12, two third slots 1213 located at the back side of the mounting flange 12 and respectively disposed between the first slot 1211 and the two second slots 1212, and two stop blocks 1214 respectively disposed between the two opposite ends of the first slot 1211 and the two second slots 1212. According to this alternate form, the insertion slot unit 121 at each mounting flange 12 of the heat sink 1 simply comprises one first slot 1211 located at the back side of the mounting flange 12 and cut through the two bevel guide facets 122. The first slot 1211 of the insertion slot unit 121 is made by linear milling. This second embodiment simplifies the manufacturing process of the heat sink-based single-board computer holder assembly to reduce the cost.

In the aforesaid embodiments, the screw rod 212 of each fastening member 21 of the positioning mechanism 2 is inserted through the through holes 221 of the respective two wedge-shaped sliding blocks 22 with the outer thread 2121 thereof thread meshed with the inner thread 2211 in the through hole 221 of one wedge-shaped sliding block 22. When fastening up each fastening member 21, the beveled stop facets 222 of the respective two wedge-shaped sliding blocks 22 are moved along the respective bevel guide facets 122 at the respective mounting flange 12 of the heat sink 1. In actual application, the inner thread 2211 can be eliminated from the through hole 221 of the respective wedge-shaped sliding block 22. In this case, the screw rod 212 of each fastening member 21 is inserted through the through hole 221 of the respective two wedge-shaped sliding blocks 22 with the outer thread 2121 thereof threaded into the inner thread 231 of one respective screw nut 23. Thus, the user can insert a hand tool (such as hex wrench) through the notch 124 at the respective mounting flange 12 and then operate the hand tool to rotate the screw nut 23 in fastening up the screw nut 23 at the screw rod 212 of the respective fastening member 21. When rotating the screw nut 23 at this time, the screw rod 212 of the fastening member 21 is moved to carry the respective two wedge-shaped sliding blocks 22 toward each other, forcing the two wedge-shaped sliding blocks 22 and the respective mounting flange 12 to abut against the respective guide portion of the machine housing for transferring heat.

Although particular embodiments of the invention have been described in detail for purposes of illustration, various modifications and enhancements may be made without departing from the spirit and scope of the invention. Accordingly, the invention is not to be limited except as by the appended claims.

What the invention claimed is:

1. A heat sink-based single-board computer holder assembly, comprising:
a heat sink comprising a base, two mounting flanges respectively extended from opposing top and bottom sides of said base, an insertion slot unit transversely located at each said mounting flange and two bevel guide facets located at each said mounting flange and sloping forwardly inwards and respectively disposed at two opposite ends of the associating said insertion slot unit, each said insertion slot unit comprising a first slot located at a front side of the respective said mounting flange between the respective said two bevel guide facets, a second slot located at each said bevel guide facet, a plurality of third slots located at an opposing back side of the respective said mounting flange and respectively disposed between said first slot and said two second slots and two stop blocks respectively disposed between two opposite ends of said first slot and said two second slots;
a positioning mechanism comprising two fastening members respectively inserted through said insertion slot units at said two mounting flanges of said heat sink and two pair of wedge-shaped sliding blocks respectively bilaterally mounted on said mounting flanges of said heat sink, each said wedge-shaped sliding block comprising a through hole cut through opposing front and back sides thereof, a beveled stop facet located at the front side thereof and abutted against one respective said bevel guide facet of said heat sink and a planar abutment surface located at the periphery thereof and extended from a border side of said beveled stop facet, each said fastening member being rotatable to move the respective said two wedge-shaped sliding blocks along the respective said bevel guide facets between a first position where said abutment surface of each said wedge-shaped sliding block is protruded over the front side of the respective said mounting flange and a second position where said abutment surface of each said wedge-shaped sliding block is retracted below the respective said mounting flange.

2. The heat sink-based single-board computer holder assembly as claimed in claim 1, wherein said base of said heat sink is plate shaped, having two opposite long sides respectively located at the opposing top and bottom sides thereof; said first slot, said second slots and said third slots of each said insertion slot unit at the respective said mounting flange is linearly formed by milling.

3. The heat sink-based single-board computer holder assembly as claimed in claim 1, wherein said heat sink further comprises two stepped guideways located at each said mounting flange and respectively outwardly extended from the respective said two bevel guide facets in reversed directions and respectively adapted for supporting one respective said wedge-shaped sliding block and guiding movement of the respective said wedge-shaped sliding block between said locking position and said unlocking position.

4. The heat sink-based single-board computer holder assembly as claimed in claim 3, wherein said heat sink further comprises a notch located at each said mounting flange and extended from one said stepped guideway to the back side of the respective said mounting flange.

5. The heat sink-based single-board computer holder assembly as claimed in claim 1, wherein each said fastening member of said positioning mechanism comprises a screw rod inserted the through holes of the respective said two wedge-shaped sliding blocks and one said insertion slot unit of said heat sink, a head located at one end of said screw rod and an outer thread extending around the periphery of an opposite end of said screw rod, said screw rod having an outer diameter smaller than an inner dimension of said insertion slot unit; one of said two wedge-shaped sliding blocks of the same pair defining an inner thread in the through hole thereof for receiving said outer thread of the respective said fastening member.

6. The heat sink-based single-board computer holder assembly as claimed in claim 1, wherein each said fastening member of said positioning mechanism comprises a screw rod inserted the through holes of the respective said two wedge-shaped sliding blocks and one said insertion slot unit of said heat sink, a head located at one end of said screw rod, an outer thread extending around the periphery of an opposite end of said screw rod and a screw nut threaded onto said outer thread and stopped at an outer side of one said wedge-shaped sliding block, said screw rod having an outer diameter smaller than an inner dimension of said insertion slot unit; one of said two wedge-shaped sliding blocks of the same pair defining an inner thread in the through hole thereof for receiving said outer thread of the respective said fastening member.

7. A heat sink-based single-board computer holder assembly, comprising:
a heat sink comprising a base, two mounting flanges respectively extended from opposing top and bottom sides of said base, an insertion slot unit transversely located at each said mounting flange and two bevel guide facets located at each said mounting flange and sloping forwardly inwards and respectively disposed at two opposite ends of the associating said insertion slot unit, each said insertion slot unit comprising a first slot located at a back side of the respective said mounting flange and extending through the respective said two bevel guide facets; and
a positioning mechanism comprising two fastening members respectively inserted through said insertion slot units at said two mounting flanges of said heat sink and two pair of wedge-shaped sliding blocks respectively bilaterally mounted on said mounting flanges of said heat sink, each said wedge-shaped sliding block comprising a through hole cut through opposing front and back sides thereof, a beveled stop facet located at the front side thereof and abutted against one respective said bevel guide facet of said heat sink and a planar abutment surface located at the periphery thereof and extended from a border side of said beveled stop facet, each said fastening member being rotatable to move the respective said two wedge-shaped sliding blocks along the respective said bevel guide facets between a locking position where said abutment surface of each said wedge-shaped sliding block is protruded over a front side of the respective said mounting flange and an unlocking position where said abutment surface of each said wedge-shaped sliding block is retracted below the respective said mounting flange.

8. The heat sink-based single-board computer holder assembly as claimed in claim 7, wherein said base of said heat sink is plate shaped, having two opposite long sides respectively located at the opposing top and bottom sides thereof; said first slot of each said insertion slot unit at the respective said mounting flange is linearly formed by milling.

9. The heat sink-based single-board computer holder assembly as claimed in claim 7, wherein said heat sink further comprises two stepped guideways located at each said mounting flange and respectively outwardly extended from the respective said two bevel guide facets in reversed directions and respectively adapted for supporting one respective said wedge-shaped sliding block and guiding movement of the respective said wedge-shaped sliding block between said locking position and said unlocking position.

10. The heat sink-based single-board computer holder assembly as claimed in claim 7, wherein each said fastening member of said positioning mechanism comprises a screw rod inserted the through holes of the respective said two wedge-shaped sliding blocks and one said insertion slot unit of said heat sink, a head located at one end of said screw rod, an outer thread extending around the periphery of an opposite end of said screw rod and a screw nut threaded onto said outer thread and stopped at an outer side of one said wedge-shaped sliding block, said screw rod having an outer diameter smaller than an inner dimension of said insertion slot unit; one of said two wedge-shaped sliding blocks of the same pair defining an inner thread in the through hole thereof for receiving said outer thread of the respective said fastening member.
